(19) United States
(12) Patent Application Publication
(10) Pub. No.: US 2013/0316507 A1
(43) Pub. Date: Nov. 28, 2013

(54) METHOD FOR MANUFACTURING NITRIDE SEMICONDUCTOR ELEMENT

(71) Applicants: Yu Saitoh, Itami-shi (JP); Masaya Okada, Osaka-shi (JP); Masaki Ueno, Itami-shi (JP); Makoto Kiyama, Itami-shi (JP)

(72) Inventors: Yu Saitoh, Itami-shi (JP); Masaya Okada, Osaka-shi (JP); Masaki Ueno, Itami-shi (JP); Makoto Kiyama, Itami-shi (JP)

(73) Assignee: SUMITOMO ELECTRIC INDUSTRIES, LTD., Osaka-shi (JP)

(21) Appl. No.: 13/981,856

(22) PCT Filed: Aug. 24, 2011
(86) PCT No.: PCT/JP2011/069085

§ 371 Date: Aug. 16, 2013

(30) Foreign Application Priority Data
Jan. 25, 2011 (JP) 2011-013210

(51) Int. Cl. H01L 29/20

(52) U.S. Cl. CPC H01L 29/2003
USPC 438/285; 438/309

(57) ABSTRACT

A method for manufacturing a heterojunction field effect transistor 1 comprises the steps of: epitaxially growing a drift layer 20a on a support substrate 10; epitaxially growing a current blocking layer 20b which is a p-type semiconductor layer on the drift layer 20a at a temperature equal to or higher than 1000° C. by using hydrogen gas as a carrier gas; and epitaxially growing a contact layer 20c on the current blocking layer 20b by using at least one gas selected from the group consisting of nitrogen gas, argon gas, helium gas, and neon gas as a carrier gas.

### TECHNICAL FIELD

The present invention relates to a method for manufacturing a nitride semiconductor device.

### BACKGROUND ART

Patent Literature 1 discloses a heterojunction field effect transistor (HFET) having a vertical transistor structure in which an n-type GaN drift layer, a p-type GaN barrier layer, and an n-type GaN cap layer are formed in the order of description on a conductive substrate. In the transistor described in Patent Literature 1, an opening is formed from the n-type GaN cap layer to the n-type GaN drift layer through the p-type GaN barrier layer, and an electron transit layer and an electron supply layer are fowled in the order of description on the side surface of the opening.

The transistor described in Patent Literature 1 is manufactured by forming the n-type GaN drift layer, p-type GaN barrier layer, and n-type GaN cap layer in the order of description on the conductive substrate by a MOCVD method or the like, then forming the opening from the n-type GaN cap layer to the n-type GaN drift layer through the p-type GaN barrier layer, and forming the electron transit layer and the electron supply layer in the order of description on the side surface of the opening.

### CITATION LIST

### Patent Literature

Patent Literature 1: Japanese Patent Application Publication No. 2006-286942

### Non Patent Literature

Non Patent Literature 1: Appl. Phys. Lett., Vol. 72, No. 14, 6 Apr. 1998

### SUMMARY OF INVENTION

### Technical Problem

When a semiconductor layer is formed, a gas including hydrogen atoms, such as ammonia (NH₃) gas used to inhibit the decomposition of semiconductor crystals or hydrogen (H₂) gas used as a carrier gas, is sometimes introduced into the growth furnace. In the case in which a device is formed with a p-type semiconductor layer being exposed to the outside, where the ammonia gas or hydrogen gas remains inside the growth furnace when the temperature is lowered after the p-type semiconductor layer has been formed at a high temperature, hydrogen atoms derived from the ammonia gas or hydrogen gas are taken in the p-type semiconductor layer, and those hydrogen atoms can form bonds (passivation) with the dopant (for example, Mg) and the acceptor concentration of the p-type semiconductor layer can be insufficient (see, for example, Non Patent Literature 1). By contrast, where activation annealing is performed in a nitrogen atmosphere after the p-type semiconductor layer has been formed, hydrogen atoms contained in the p-type semiconductor layer dissociate from the dopant and are released to the outside of the device, thereby making it possible to activate the dopant.

In a nitride semiconductor device such as the transistor described in Patent Literature 1, it is required to improve the degree of activity of the dopant in the p-type semiconductor layer, cause the current block of the pn interface to function, and inhibit the drain leakage, and a step of performing the activation annealing after the semiconductor multilayer structure has been formed can be considered. However, the inventors have established that even when the activation annealing is performed with respect to the transistor described in Patent Literature 1 to dissociate hydrogen atoms from the dopant, the n-type GaN cap layer acts as a barrier for hydrogen atoms because the annealing is performed in a state that the n-type GaN cap layer has been laminated on the p-type GaN barrier layer. As a result, hydrogen atoms are prevented from being released from the p-type GaN barrier layer to the outside of the device, and it is difficult to cause the p-type GaN barrier layer to function so as to inhibit the drain leakage.

Where the dopant contained in the p-type GaN barrier layer is not sufficiently activated, as mentioned hereinabove, the interface of the n-type GaN drift layer and the p-type GaN barrier layer does not have sufficient electrical functionality, drain leakage (current leakage) occurs, and a pinch-off characteristic is degraded.

The present invention has been accomplished with consideration for such a problem, and it is an object to provide a method for manufacturing a nitride semiconductor device in which the drain leakage current can be reduced.

### Solution to Problem

The inventors have conducted a diligent study to solve the abovementioned problem and have reached following findings. Using an inactive gas (for example, nitrogen gas), which is different from hydrogen gas, as a carrier gas in a step of forming a p-type semiconductor layer is considered as a method for solving the abovementioned problem from the standpoint of preventing incorporation of hydrogen atoms into the p-type semiconductor layer. However, where an inactive gas such as nitrogen gas is used in the step of forming the p-type semiconductor layer, a compensating impurity such as oxygen is easily incorporated into the p-type semiconductor layer. Further, where the dopant contained in the p-type semiconductor layer is compensated by the incorporated compensating impurity, the acceptor concentration of the p-type semiconductor layer decreases and the occurrence of drain leakage defect is facilitated.

Meanwhile, where hydrogen gas is used as a carrier gas in the step of forming the p-type semiconductor layer, the compensating impurity can be sufficiently prevented from incorporating into the p-type semiconductor layer, and the drain leakage current can be reduced by comparison with that in the case in which an inactive gas such as nitrogen gas is used. Further, although hydrogen gas serves as a hydrogen atom supply source, by forming the p-type semiconductor layer at a high temperature, it is possible to prevent the dopant contained in the p-type semiconductor layer from forming bonds with the hydrogen atoms, while reducing the hydrogen concentration of the p-type semiconductor layer. Therefore, by forming the p-type semiconductor layer at a high temperature using hydrogen gas as a carrier gas, the compensating impurities are prevented from incorporating into the p-type semiconductor layer, and the dopant contained in the p-type semiconductor layer can be prevented from forming bonds with hydrogen atoms, while reducing the hydrogen concentration of the p-type semiconductor layer.

Thus, a method for manufacturing a nitride semiconductor device according to one aspect of the present invention comprises the steps of: epitaxially growing a first gallium nitride based semiconductor layer on a free-standing Group III nitride substrate; epitaxially growing a second gallium nitride based semiconductor layer which is a p-type semiconductor layer on the first gallium nitride based semiconductor layer at a temperature equal to or higher than 1000° C. by using hydrogen gas as a carrier gas; and epitaxially growing a third gallium nitride based semiconductor layer on the second gallium nitride based semiconductor layer by using at least one gas selected from the group consisting of nitrogen gas, argon gas, helium gas, and neon gas as a carrier gas.

In the one aspect of the present invention, the second gallium nitride based semiconductor layer which is a p-type semiconductor layer is epitaxially grown at a temperature equal to or higher than 1000° C. by using hydrogen gas as a carrier gas. As a result, compensating impurities are prevented from incorporating into the second gallium nitride based semiconductor layer, and the dopant contained in the second gallium nitride based semiconductor layer can be prevented from forming bonds with hydrogen atoms, while reducing the amount of hydrogen atoms incorporating into the second gallium nitride based semiconductor layer. Further, in the one aspect of the present invention, the third gallium nitride based semiconductor layer is epitaxially grown by using at least one gas selected from the group consisting of nitrogen gas, argon gas, helium gas, and neon gas as a carrier gas. Since these gases are unlikely to be a supply source for hydrogen atoms, by using these gases as a carrier gas, it is possible to prevent hydrogen atoms from being taken in the second gallium nitride based semiconductor layer in the step of epitaxially growing the third gallium nitride based semiconductor layer. Further, in the one aspect of the present invention, the third gallium nitride based semiconductor layer is epitaxially grown on the second gallium nitride based semiconductor layer. As a result, the second gallium nitride based semiconductor layer is prevented from being exposed to the outside, therefore, hydrogen atoms can be prevented from being taken in the second gallium nitride based semiconductor layer and deactivating the dopant. In the above-described one aspect of the present invention, the acceptor concentration of the second gallium nitride based semiconductor layer is prevented from being insufficient, therefore, the interface of the first gallium nitride based semiconductor layer and the second gallium nitride based semiconductor layer has sufficient electrical functionality. As a result, the drain leakage current in the nitride semiconductor device can be reduced.

The third gallium nitride based semiconductor layer is preferably an n-type semiconductor layer. In this case, hydrogen atoms are further prevented from passing through the third gallium nitride based semiconductor layer and reaching the second gallium nitride based semiconductor layer, therefore, the drain leakage current can be further reduced.

The first gallium nitride based semiconductor layer may be an n-type semiconductor layer. In this case, a pn junction can be formed at the interface of the first gallium nitride based semiconductor layer and the second gallium nitride based semiconductor layer.

The second gallium nitride based semiconductor layer may include at least one element selected from the group consisting of magnesium and zinc as a dopant. In this case, the second gallium nitride based semiconductor layer can be formed efficiently. Further, although magnesium and zinc tend to be easily deactivated by forming bonds with hydrogen atoms, according to the one aspect of the present invention, the drain leakage current can be reduced even when magnesium and zinc are used as dopants.

The ratio of a hydrogen concentration to an acceptor concentration in the second gallium nitride based semiconductor layer is preferably less than 0.8. In this case, the dopant contained in the second gallium nitride based semiconductor layer can be sufficiently prevented from deactivation, therefore, the electrical functionality of the second gallium nitride based semiconductor layer is further improved and the drain leakage current can be further reduced.

The thickness of the third gallium nitride based semiconductor layer is preferably 50 to 500 nm. In this case, the electrical functionality of the third gallium nitride based semiconductor layer can be further improved, while maintaining the flatness of the surface of the third gallium nitride based semiconductor layer.

A combination of materials of the first to third gallium nitride based semiconductor layers is preferably n⁺-type GaN/p-type GaN/n-type GaN, n⁺-type GaN/p-type AlGaN/n-type GaN, n⁺-type InGaN/p-type GaN/n-type GaN, or n⁺-type InGaN/p-type AlGaN/n-type GaN when represented as the third gallium nitride based semiconductor layer/the second gallium nitride based semiconductor layer/the first gallium nitride based semiconductor layer. With such combinations, a favorable pn junction can be provided and the drain leakage current can be further reduced.

The method for manufacturing a nitride semiconductor device according to the one aspect of the present invention may have a configuration in which the method further comprise the steps of: forming an opening in the first gallium nitride based semiconductor layer for a drift layer, the second gallium nitride based semiconductor layer for a current blocking layer, and the third gallium nitride based semiconductor layer for a contact layer, the opening passing from the third gallium nitride based semiconductor layer to the first gallium nitride based semiconductor layer through the second gallium nitride based semiconductor layer, to obtain a laminate having the drift layer, the current blocking layer, the contact layer, and the opening; epitaxially growing a channel layer constituted by a gallium nitride based semiconductor on a side surface of the opening; epitaxially growing a carrier supply layer constituted by a Group III nitride semiconductor on the channel layer; forming an insulating film on the carrier supply layer; and forming a gate electrode on the insulating film, forming a source electrode on the laminate, and forming a drain electrode on the free-standing Group III nitride substrate or on the laminate, wherein a bandgap of the carrier supply layer is greater than a bandgap of the channel layer.

The method for manufacturing a nitride semiconductor device according to the one aspect of the present invention may have a configuration in which the nitride semiconductor device is a bipolar transistor comprising a collector layer, a base layer, and an emitter layer, the collector layer is the first gallium nitride based semiconductor layer, the base layer is the second gallium nitride based semiconductor layer containing indium, and the emitter layer is the third gallium nitride based semiconductor layer.

### Advantageous Effects of Invention

According to the one aspect of the present invention, it is possible to provide a method for manufacturing a nitride semiconductor device in which the drain leakage current can be reduced. In particular, according to the one aspect of the present invention, it is possible to provide a method for manufacturing a nitride semiconductor device in which the drain leakage current can be reduced without performing heat treatment for activating the dopant. Further, according to the one aspect of the present invention, it is possible to provide a method for manufacturing a transistor for power control that has a vertical structure.

### BRIEF DESCRIPTION OF DRAWINGS

FIG. 1 is a cross-sectional view illustrating schematically a nitride semiconductor device manufactured by the manufacturing method according to one embodiment of the present invention.

FIG. 2 is a cross-sectional view illustrating schematically the steps of the method for manufacturing a nitride semiconductor device according to one embodiment of the present invention.

FIG. 3 is a cross-sectional view illustrating schematically the steps of the method for manufacturing a nitride semiconductor device according to one embodiment of the present invention.

FIG. 4 is a cross-sectional view illustrating schematically the steps of the method for manufacturing a nitride semiconductor device according to one embodiment of the present invention.

FIG. 5 is a cross-sectional view illustrating schematically a nitride semiconductor device manufactured by the manufacturing method according to another embodiment of the present invention.

FIG. 6 is a cross-sectional view illustrating schematically a nitride semiconductor device manufactured by the manufacturing method according to another embodiment of the present invention.

FIG. 7 is a view illustrating the measurement results of ECV measurements.

### DESCRIPTION OF EMBODIMENTS

A method for manufacturing a nitride semiconductor device according to one embodiment of the present invention will be explained below with reference to the appended drawings. In the drawings, when possible, identical components are designated by the same reference numerals. The dimensional ratios within and between the constituent elements in the drawings are arbitrary, having been selected to make the drawings clear.

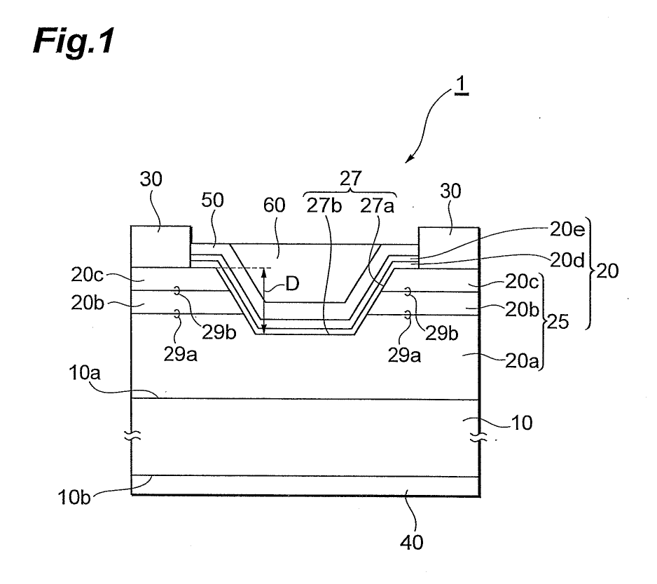

FIG. 1 is a cross-sectional view illustrating schematically the nitride semiconductor device manufactured by the manufacturing method according to the present embodiment. As shown in FIG. 1, a heterojunction field effect transistor 1 has a vertical transistor structure and comprises a support substrate 10, a semiconductor region 20, a source electrode 30, a drain electrode 40, an insulating film 50, and a gate electrode 60.

The support substrate 10 is a gallium nitride based semiconductor substrate, such as a GaN substrate, which is a conductive free-standing Group III nitride substrate. The support substrate 10 has a front surface (principal surface) 10a and a rear surface (principal surface) 10b which face each other.

The semiconductor region 20 is disposed on the front surface 10a of the support substrate 10. The semiconductor region 20 has a drift layer 20a, a current blocking layer 20b, a contact layer 20c, a channel layer 20d, and a carrier supply layer 20e.

The drift layer 20a, the current blocking layer 20b, and the contact layer 20c are laminated in the order of description on the front surface 10a of the support substrate 10, thereby forming a laminate (semiconductor laminate) 25, and an opening 27 is formed from the contact layer 20c to the drift layer 20a through the current blocking layer 20b at the front surface side of the laminate 25. The opening 27 extends in a predetermined direction along the front surface 10a of the support substrate 10, and FIG. 1 shows a cut surface in the direction orthogonal to this predetermined direction.

The opening 27 has a side surface 27a and a bottom surface 27b. The side surface 27a is constituted by the side surfaces of the drift layer 20a, current blocking layer 20b, and contact layer 20c and inclined toward the bottom surface 27b side. The bottom surface 27b of the opening 27 is constituted by the drift layer 20a and connected to the side surface 27a.

The drift layer 20a is disposed on the front surface 10a so as to cover the entire front surface 10a of the support substrate 10. A recess constituting the bottom section of the opening 27 is formed at the front surface side of the drift layer 20a. The drift layer 20a is a gallium nitride based semiconductor layer constituted by GaN, AlGaN, InGaN, InAlGaN or the like, and is, for example, an n-type semiconductor layer including an n-type dopant (Si or the like). The donor concentration of the drift layer 20a is, for example, 5×10¹⁵ to 2×10¹⁶ cm⁻³. The thickness of the drift layer 20a is, for example, 3 to 12 μm in the region where the recess has not been formed.

The current blocking layer (barrier layer) 20b is disposed on the regions where the recess has not been formed in the drift layer 20a and is in contact with the drift layer 20a. The current blocking layer 20b is a gallium nitride based semiconductor layer constituted by GaN, AlGaN, InGaN, InAlGaN or the like, and when this layer is constituted by AlGaN, the diffusion of the dopant from the current blocking layer 20b to the contact layer 20c or the channel layer 20d can be sufficiently inhibited.

The current blocking layer 20b is a p-type semiconductor layer including at least one element selected from the group consisting of magnesium (Mg) and zinc (Zn) as a p-type dopant. For example, a pn junction 29a is formed between the current blocking layer 20b and the drift layer 20a. From the standpoint of enabling the pn junction 29a to function effectively and maintaining the drain voltage resistance, it is preferred that the acceptor concentration of the current blocking layer 20b be equal to or higher than 1×10¹⁷ cm⁻³, more preferably equal to or higher than 1×10¹⁸ cm⁻³. From the standpoint of inhibiting the increase in on-resistance by diffusion of the dopant from the current blocking layer 20b into the channel layer 20d, it is preferred that the acceptor concentration of the current blocking layer 20b be equal to or lower than 5×10¹⁸ cm⁻³.

Where the concentration of hydrogen in the current blocking layer 20b is high, the hydrogen atoms form bonds with the dopant and the activity of the dopant is easily decreased. Therefore, from the standpoint of further inhibiting the reduction in dopant activity, it is preferred that the ratio of hydrogen concentration to the acceptor concentration in the current blocking layer 20b (hydrogen concentration/acceptor concentration) be less than 0.8, more preferably equal to or less than 0.7. The hydrogen concentration can be adjusted by the type of atmosphere gas or growth temperature and can be measured by secondary ion mass spectrometry (SIMS) or the like.

From the standpoint of enabling the pn junction 29a to function effectively and maintaining the drain voltage resistance, it is preferred that the thickness of the current blocking layer 20b be equal to or greater than 0.5 μm. Since the on-resistance of the transistor increases proportionally to the thickness of the current blocking layer 20b, it is preferred that the thickness of the current blocking layer 20b be equal to or less than 2 μm, more preferably equal to or less than 1 μm.

The contact layer 20c is disposed on the current blocking layer 20b and is in contact with the current blocking layer 20b. The contact layer 20c is a gallium nitride based semiconductor layer constituted by GaN, AlGaN, InGaN, InAlGaN or the like, and when it is constituted by InGaN that has a small bandgap, the diffusion of hydrogen atoms in the current blocking layer 20b can be enhanced.

The contact layer 20c is, for example, an n-type semiconductor layer including an n-type dopant (Si or the like). For example, a pn junction 29b is formed between the contact layer 20c and the current blocking layer 20b. From the standpoint of reducing the series resistance between the source electrode 30 and the channel layer 20d, it is preferred that the donor concentration of the contact layer 20c be equal to or higher than 1×10¹⁸ cm⁻³. From the standpoint of inhibiting the introduction of compensation-type defects caused by an excess amount of donors, it is preferred that the donor concentration of the contact layer 20c be equal to or less than 1×10¹⁹ cm⁻³, more preferably equal to or less than 5×10¹⁸ cm⁻³. When the contact layer 20c is an n-type semiconductor layer, incorporation of a compensating impurity such as oxygen contributes to the increase in the number of carriers, and the carrier gas including such compensating impurities can be used when the contact layer 20c is formed.

From the standpoint of enabling sufficient electrical functionality of the contact layer 20c even when the dopant diffuses from the current blocking layer 20b into the contact layer 20c, it is preferred that the thickness of the contact layer 20c be equal to or greater than 0.05 μm (50 nm), more preferably equal to or greater than 0.2 μm (200 nm). From the standpoint of maintaining the surface flatness of the contact layer 20c, it is preferred that the thickness of the contact layer 20c be equal to or less than 0.5 μm (500 nm), more preferably equal to or less than 0.3 μm (300 nm).

The combination of materials of the drift layer 20a, current blocking layer 20b, and contact layer 20c is preferably, n⁺-type GaN/p-type GaN/n-type GaN, n⁺-type GaN/p-type AlGaN/n-type GaN, n⁺-type InGaN/p-type GaN/n-type GaN, or n⁺-type InGaN/p-type AlGaN/n-type GaN when represented as the contact layer 20c/the current blocking layer 20b/the drift layer 20a. With such combinations, a favorable pn junction can be provided and the drain leakage current can be further reduced.

The channel layer 20d is disposed on the side surface 27a and the bottom surface 27b of the opening 27 along the shape of the opening 27 and comes into contact with the respective side surfaces of the drift layer 20a, current blocking layer 20b, and contact layer 20c exposed in the opening 27. Further, the channel layer 20d covers a region in the vicinity of the opening 27 at the principal surface of the contact layer 20c. The channel layer 20d is a gallium nitride based semiconductor layer constituted by GaN, AlGaN, InGaN, InAlGaN or the like, and is, for example, undoped. The thickness of the channel layer 20d is, for example, 50 to 200 nm.

The carrier supply layer (barrier layer) 20e is disposed on the channel layer 20d along the shape of the opening 27 and comes into contact with the channel layer 20d. The carrier supply layer 20e is a Group III nitride semiconductor layer constituted by AlN, GaN, AlGaN, InGaN, InAlGaN or the like, and is, for example, undoped. The thickness of the carrier supply layer 20e is, for example, 5 to 30 nm. From the standpoint of forming a well-type potential at the interface of the carrier supply layer 20e and the channel layer 20d and realizing a function of confining the two-dimensional electron gas, it is preferred that the bandgap of the carrier supply layer 20e be greater than the bandgap of the channel layer 20d.

The combination of materials of the channel layer 20d and the carrier supply layer 20e is preferably InGaN/AlGaN, GaN/AlGaN, or AlGaN/AlN when represented as the channel layer 20d/the carrier supply layer 20e. With such combinations, favorable carrier generation and favorable channel formation can be ensured.

The source layer 30 is formed on the region not covered by the channel layer 20d on the principal surface of the contact layer 20c, and the side surface of the source layer 30 comes into contact with the end sections of the channel layer 20d and the carrier supply layer 20e. For example, Ti/Al can be used for the source electrode 30.

The drain electrode 40 is disposed on the support substrate 10 or the laminate 25. In the present embodiment, the drain electrode 40 is disposed so as to cover the entire rear surface 10b of the support substrate 10. For example, Ti/Al can be used for the drain electrode 40.

The insulating film 50 is disposed on the carrier supply layer 20e along the shape of the opening 27 and forms a recess along the shape of the opening 27. The insulating film 50 is, for example, a silicon oxide film. The thickness of the insulating film 50 is, for example, about 10 nm. By disposing the insulating film 50, it is possible to increase the barrier of the gate electrode 60 against the laminate 25.

The gate electrode 60 is disposed inside the recess formed by the insulating film 50. For example, Ni/Au, Pt/Au, Pd/Au, or Mo/Au can be used as the gate electrode 60.

In the heterojunction field effect transistor 1, when the carriers are electrons, the carriers from the source electrode 30 are transported as a two-dimensional carrier gas inside the channel layer 20d. Where the voltage of the gate electrode 60 of the heterojunction field effect transistor 1 exceeds a threshold, the carriers pass through the channel layer 20d located directly below the gate electrode 60, then reach the drift layer 20a, and reach the drain electrode 40 via the rear surface 10b of the support substrate 10. In order to enable such movement of the carriers, the heterojunction field effect transistor 1 has a vertical structure.

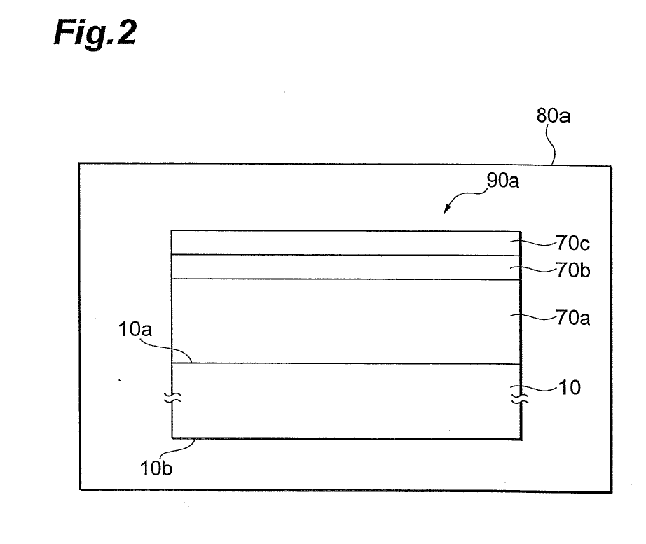

A method for manufacturing the nitride semiconductor device according to the present embodiment will be explained hereinbelow with reference to FIGS. 2 to 4. FIGS. 2 to 4 are cross-sectional views illustrating schematically the steps of the method for manufacturing the nitride semiconductor device according to the present embodiment.

The method for manufacturing the heterojunction field effect transistor 1 comprises, for example, a first semiconductor layer formation step, a second semiconductor layer formation step, a third semiconductor layer formation step, an opening formation step, a regrowth step, an insulating film formation step, and an electrode formation step in the order of description. The method for manufacturing the heterojunction field effect transistor 1 may comprise a step of lowering the sample temperature, for example, to room temperature (25° C.) after the third semiconductor layer formation step, for example, when a transition is made from the third semiconductor layer formation step to the opening formation step, the sample may be taken out of the growth furnace used in the third semiconductor layer formation step to lower the sample temperature, and then the sample may be accommodated inside the chamber used in the opening formation step.

In the first semiconductor layer formation step, second semiconductor layer formation step, third semiconductor layer formation step, and regrowth step, the semiconductor layers can be epitaxially grown, for example, by a MOCVD method. Examples of source material gases include trimethylgallium (gallium source material), ammonia (nitrogen source material), trimethylaluminum (aluminum source material), and trimethylindium (indium source material). Examples of n-type dopant gases include silane. Examples of p-type dopant gases include biscyclopentadienyl magnesium and diethylzinc.

In the first semiconductor layer formation step, the support substrate 10 is disposed inside a growth furnace 80a such as shown in FIG. 2. In the first semiconductor layer formation step, the support substrate 10 may be heat treated to clean the front surface 10a of the support substrate 10 in an atmosphere including ammonia gas (for example, a flow rate of 16 slm (slm=standard liter/minute)) and hydrogen gas (for example, a flow rate of 4 slm) before the semiconductor layer is epitaxially grown on the support substrate 10. The heat treatment temperature is, for example, 1000 to 1100° C. The pressure inside the furnace is, for example, 50 to 760 Torr (1 Torr=133 Pa). The heat treatment time is for example, 5 min. The heat treatment can detach moisture or oxygen present at the front surface 10a of the support substrate 10.

Then, source material gases are supplied together with a carrier gas into the growth furnace 80a, and a semiconductor layer (first gallium nitride based semiconductor layer) 70a is epitaxially grown as a gallium nitride based semiconductor layer for the drift layer 20a on the front surface 10a of the support substrate 10 in the direction normal to the front surface 10a. For example, hydrogen gas is used as the carrier gas.

In the second semiconductor layer formation step, the starting material gases are supplied together with a carrier gas into the growth furnace 80a, and a semiconductor layer (second gallium nitride based semiconductor layer) 70b is epitaxially grown as a gallium nitride based semiconductor layer for the current blocking layer 20b on the semiconductor layer 70a in the direction normal to the front surface 10a. In the second semiconductor layer formation step, hydrogen gas is used as the carrier gas. High-purity hydrogen gas can be easily introduced into the growth furnace 80a by using a palladium permeation membrane.

From the standpoint of preventing the dopant contained in the semiconductor layer 70b from forming bonds with hydrogen atoms, while reducing hydrogen concentration of the semiconductor layer 70b, the growth temperature in the second semiconductor layer formation step is equal to or higher than 1000° C., preferably equal to or higher than 1040° C., more preferably equal to or higher than 1050° C. The upper limit for the growth temperature is, for example, 1100° C. The growth pressure is preferably 50 to 760 Torr, more preferably 200 to 760 Torr. The supply molar ratio (V/III) as represented by (molar amount of supplied ammonia)/(molar amount of supplied organic gallium source material) is preferably, for example, 500 to 10000.

In the third semiconductor layer formation step, the source material gases are supplied together with a carrier gas into the growth furnace 80a, and a semiconductor layer (third gallium nitride based semiconductor layer) 70c is epitaxially grown as a gallium nitride based semiconductor layer for the contact layer 20c on the semiconductor layer 70b in the direction normal to the front surface 10a. As a result, a laminate 90a is formed, as shown in FIG. 2. In the third semiconductor layer formation step, at least one inactive gas selected from the group consisting of nitrogen gas, argon gas, helium gas, and neon gas is used, instead of the hydrogen gas used in the second semiconductor layer formation step, as the carrier gas.

The growth temperature in the third semiconductor layer formation step is preferably 1000 to 1100° C., more preferably 1050 to 1100° C. In the present embodiment, the second semiconductor layer formation step and the third semiconductor layer formation step are preferably performed continuously. Further, in the continuous process of the second semiconductor layer formation step and the third semiconductor layer formation step, the semiconductor layer 70b is preferably maintained at a temperature equal to or higher than 1000° C., in this case, the state in which the dopant is dissociated from hydrogen atoms in the current blocking layer 20b can be maintained. The growth pressure is preferably 50 to 760 Torr, more preferably 200 to 760 Torr. The supply molar ratio (V/III) as represented by (molar amount of supplied ammonia)/(molar amount of supplied organic gallium source material) is preferably, for example, 500 to 10000.

In the present embodiment, as the carrier gas, hydrogen gas is used in the second semiconductor layer formation step, and at least one inactive gas selected from the group consisting of nitrogen gas, argon gas, helium gas, and neon gas is used in the third semiconductor layer formation step. In this case, from the standpoint of preventing hydrogen atoms from incorporating into the current blocking layer 20b, the use of an inactive gas such as nitrogen gas instead of the hydrogen gas can be also considered for the second semiconductor layer formation step. However, where an inactive gas such as nitrogen gas is used in the second semiconductor layer formation step, the compensating impurity such as oxygen is easily incorporated into the current blocking layer 20b. Then, where the dopant contained in the current blocking layer 20b is compensated by the incorporated compensating impurity, the acceptor concentration of the current blocking layer 20b decreases and the occurrence of drain leakage is facilitated.

Meanwhile, when hydrogen gas is used as the carrier gas in the second semiconductor layer formation step, the compensating impurities can be sufficiently prevented from incorporating into the current blocking layer 20b, and the drain leakage current can be reduced by comparison with that in the case in which an inactive gas such as nitrogen gas is used. Further, although hydrogen gas can be a supply source of hydrogen atoms, the dopant contained in the current blocking layer 20b can be prevented from forming bonds with the hydrogen atoms, while the hydrogen concentration of the current blocking layer 20b is being reduced, by forming the current blocking layer 20b at a high temperature equal to or higher than 1000° C. Therefore, by using the hydrogen gas as a carrier gas and forming the current blocking layer 20b at a high temperature, the compensating impurities are prevented from incorporating into the current blocking layer 20b, and the dopant contained in the current blocking layer 20b can be prevented from forming bonds with the hydrogen atoms, while the hydrogen concentration of the current blocking layer 20b is being reduced.

When hydrogen gas is used, the starting materials can be diffused efficiently by comparison with that in the case in which an inactive gas such as nitrogen gas is used, therefore, the growth speed, uniformity of film thickness distribution, and in-plane uniformity of dopant can be further improved.

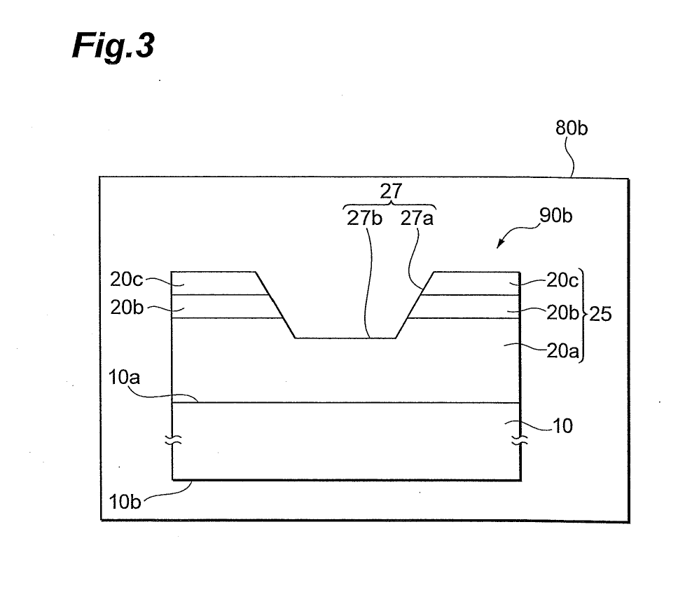

In the opening formation step, the laminate 90a is taken out of the growth furnace 80a, and the laminate 90a is then disposed inside a chamber 80b of an etching device such as shown in FIG. 3. Then, the opening 27 reaching the semiconductor layer 70a from the semiconductor layer 70c through the semiconductor layer 70b is formed at the front surface side of the laminate 90a constituted by the semiconductor layer 70a, semiconductor layer 70b, and semiconductor layer 70c, to obtain a laminate 90b having the drift layer 20a, current blocking layer 20b, contact layer 20c, and opening 27.

In the opening formation step, for example, a silicon oxide film is formed by a sputtering method on the semiconductor layer 70c, the silicon oxide film is then patterned, to form a mask layer (not shown in the figures) that has a pattern in which the region where the opening 27 will be formed is exposed. Next, reactive ion etching or the like is performed through the mask layer, parts of the semiconductor layer 70c, semiconductor layer 70b, and semiconductor layer 70a are successively removed, to form the opening 27. The mask layer can be removed by wet etching.

The regrowth step comprises a channel layer formation step and a carrier supply layer formation step. In the regrowth step, the laminate 90b may be heat treated in an atmosphere including ammonia gas (for example, a flow rate of 16 slm) and hydrogen gas (for example, a flow rate of 4 slm) before the channel layer 20d is epitaxially grown on the contact layer 20c in the channel layer formation step. As a result, the atoms can be rearranged at the front surface of the laminate 90b serving as a base for the channel layer 20d. The heat treatment temperature is, for example, 1000 to 1100° C. The pressure inside the furnace is, for example, 50 to 760 Torr. The heat treatment time is, for example, 5 min.

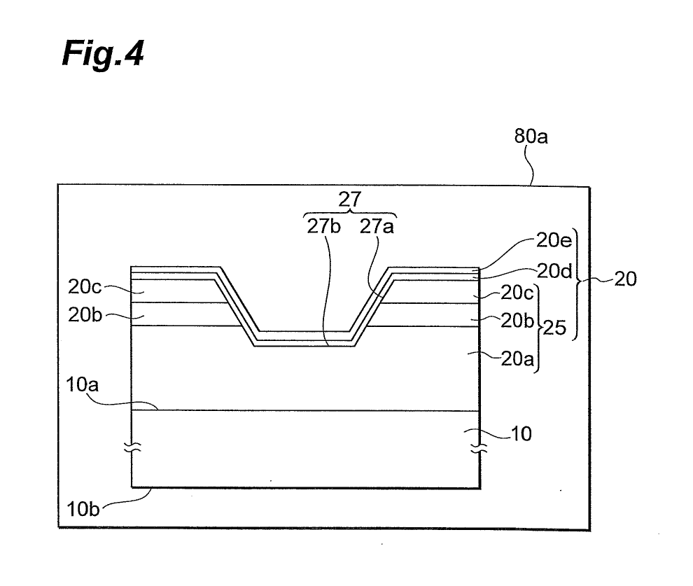

In the channel layer formation step, first, the laminate 90b is taken out of the chamber 80b, and the laminate 90b is then disposed again inside the growth furnace 80a. Next, as shown in FIG. 4, the channel layer 20d is formed such as to be in contact with the side surface 27a and the bottom surface 27b of the opening 27 and the principal surface of the contact layer 20c, along the shape of the opening 27. For example, hydrogen gas is used as the carrier gas. The growth temperature is, for example, 950 to 1050° C., the growth pressure is, for example, 50 to 760 Torr, the supply molar ratio (V/III) is, for example, 500 to 10000.

In the carrier supply layer formation step, the carrier supply layer 20e is formed on the channel layer 20d so as to cover the channel layer 20d along the shape of the opening 27. For example, hydrogen gas is used as the carrier gas. The growth temperature is, for example, 1000 to 1150° C., the growth pressure is, for example, 50 to 200 Torr, the supply molar ratio (V/III) is, for example, 500 to 10000.

In the insulating film formation step, the insulating film 50 is formed on the carrier supply layer 20e so as to cover the entire surface of the carrier supply layer 20e along the shape of the opening 27. As a result, a recess following the shape of the opening 27 is formed by the insulating film 50.

In the electrode formation step, the channel layer 20d and the carrier supply layer 20e positioned on the outer edge section of the principal surface of the contact layer 20c are removed, and then the source electrode 30 is formed on the outer edge section. The drain electrode 40 is formed on the support substrate 10 or the laminate 25. In the present embodiment, the drain electrode 40 is formed on the rear surface 10b on the side opposite that of the front surface 10a of the support substrate 10. Further, the gate electrode 60 is formed on the side surface 27a and the bottom surface 27b of the opening 27 so as to fill the recess formed by the insulating film 50.

The heterojunction field effect transistor 1 such as shown in FIG. 1 is obtained as described hereinabove.

In the present embodiment, in the second semiconductor layer formation step, the current blocking layer 20b, which is a p-type semiconductor layer, is epitaxially grown at a temperature equal to or higher than 1000° C. by using hydrogen gas as a carrier gas. As a result, the compensating impurities can be prevented from incorporating into the current blocking layer 20b, and the dopant contained in the current blocking layer 20b can be prevented from forming bonds with the hydrogen atoms, while the hydrogen concentration of the current blocking layer 20b is being reduced.

Further, in the present embodiment, in the third semiconductor layer formation step, the contact layer 20c is epitaxially grown by using at least one inactive gas selected from the group consisting of nitrogen gas, argon gas, helium gas, and neon gas as a carrier gas. Since these gases are unlikely to be the supply sources for hydrogen atoms, by using these gases as a carrier gas, it is possible to prevent hydrogen atoms from being taken in the current blocking layer 20b in the third semiconductor layer formation step.

In this case, when a device is formed in which a p-type semiconductor layer is exposed to the outside, where ammonia gas or hydrogen gas remains in the growth furnace when the temperature is lowered after the p-type semiconductor layer has been formed at a high temperature, hydrogen atoms derived from the ammonia gas or hydrogen gas are taken in the p-type semiconductor layer and a large number of dopants are deactivated by the hydrogen atoms, for example, at a room temperature attained when the sample is taken out of the growth furnace. Meanwhile, in the present embodiment, the contact layer 20c is epitaxially grown on the current blocking layer 20b. As a result, the current blocking layer 20b, which is formed while the dopant is prevented from forming bonds with hydrogen atoms, can be prevented from being exposed to the outside, therefore, hydrogen atoms can be prevented from being taken in the current blocking layer 20b and deactivating the dopant.

In the above-described embodiment, the acceptor concentration of the current blocking layer 20b is prevented from being insufficient, therefore, the pn junction 29a of the drift layer 20a and the current blocking layer 20b has sufficient electrical functionality. Therefore, the drain leakage current in the heterojunction field effect transistor 1 can be reduced.

Further, when a p-type semiconductor layer is covered by a cap layer, as in the conventional configuration, the cap layer acts as a barrier for hydrogen atoms even if the activation annealing is performed and the hydrogen atoms are dissociated from the dopant. Therefore, the release of hydrogen atoms from the p-type semiconductor layer to the outside of the device is inhibited and functions of the current blocking layer 20b serving for inhibiting the drain leakage cannot be fully realized. Particularly, such a phenomenon is notably confirmed when the cap layer is an n-type semiconductor layer or a non-doped semiconductor layer. This phenomenon apparently originates because hydrogen atoms do not diffuse significantly in an n-type semiconductor layer or a non-doped semiconductor layer, as compared with a p-type semiconductor layer, although hydrogen atoms can diffuse, while hopping, between the most stable arrangement positions that vary according to the Fermi level in the semiconductor (for example, GaN) subjected to heat treatment. Meanwhile, in the present embodiment, the current blocking layer 20b is capped by the contact layer 20c in a state in which the dopant is prevented from forming bonds with hydrogen atoms, therefore, the dopant contained in the current blocking layer 20b can be prevented from deactivation without the heat treatment such as activation annealing.

Further, in the present embodiment, a two-dimensional electron gas is generated by piezo polarization derived from the lattice distortion at the interface of the channel layer 20d and the carrier supply layer 20e formed on the side surface 27a of the opening 27, and this two-dimensional electron gas serves an electric current from the contact layer 20c to the drift layer 20a. In this case, when the dopant contained in the current blocking layer 20b is not sufficiently activated, the two-dimensional electron gas at the interface of the channel layer 20d and the carrier supply layer 20e is not depleted by the insufficient rise in the potential of the current blocking layer 20b. As a result, drain leakage defect occurs in the transistor operation and the pinch-off characteristic is degraded. However, in the present embodiment, the acceptor concentration of the current blocking layer 20b is prevented from being insufficient and, therefore, the drain leakage current can be reduced, and the pinch-off characteristic can be prevented from degrading.

Further, when the dopant contained in the current blocking layer 20b is deactivated, the increase in the doping amount of the dopant in the current blocking layer 20b can be considered from the standpoint of increasing the acceptor concentration. However, in this case, the dopant can easily diffuse from the current blocking layer 20b to the interface of the channel layer 20d and the carrier supply layer 20e, the amount of the two-dimensional electron gas present at the interface decreases, and the on-resistance during on-operation of the transistor increases. Meanwhile, in the present embodiment, the deactivation of the dopant contained in the current blocking layer 20b is inhibited and, therefore, the doping amount of the dopant can be confined to as low an amount as possible. As a result, in the present embodiment, the drain leakage current can be reduced, while inhibiting the increase in the on-resistance, during the on-operation of the transistor.

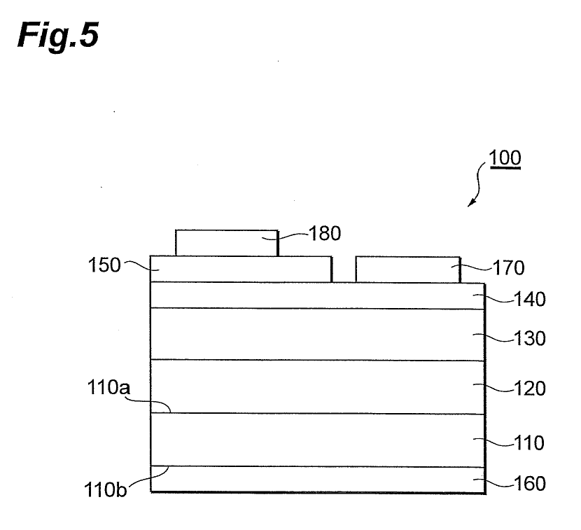

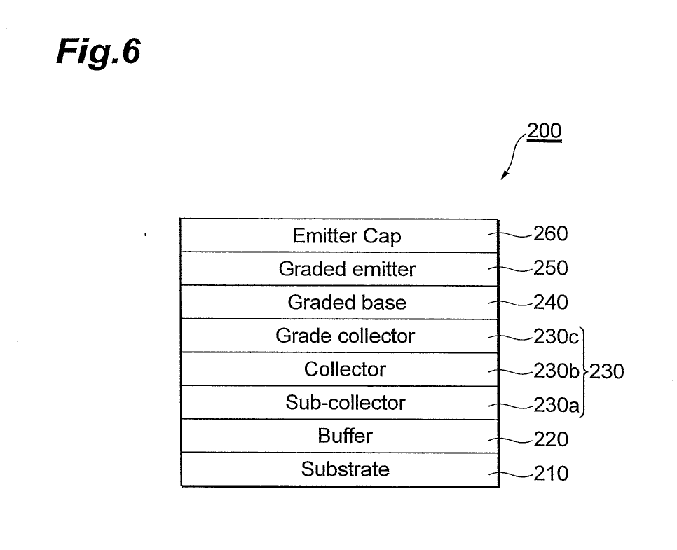

The present invention is not limited to the above-described embodiment and can be changed variously. For example, the nitride semiconductor device is not limited to the above-described transistor and may be an npn-type bipolar transistor such as shown in FIGS. 5 and 6.

A bipolar transistor 100 shown in FIG. 5 comprises a support substrate 110, a buffer layer 120, a collector layer (first gallium nitride based semiconductor layer) 130, a base layer (second gallium nitride based semiconductor layer) 140, an emitter layer (third gallium nitride based semiconductor layer) 150, a collector electrode 160, a base electrode 170, and an emitter electrode 180.

The support substrate 110 is a free-standing Group III nitride substrate, such as a GaN substrate. The buffer layer 120 is disposed on a front surface 110a of the support substrate 110. The buffer layer 120 is a gallium nitride based semiconductor layer including an n-type dopant such as Si, for example an n-type GaN layer.

The collector layer 130 is disposed on the principal surface of the buffer layer 120. The collector layer 130 is a gallium nitride based semiconductor layer including an n-type dopant such as Si, for example an n-type GaN layer.

The base layer 140 is disposed on the principal surface of the collector layer 130. The base layer 140 is a gallium nitride based semiconductor layer containing indium, and is a p-type semiconductor layer including a p-type dopant such as Mg and Zn. The base layer 140 is, for example, a p-type InGaN layer.

The emitter layer 150 is disposed on the principal surface of the base layer 140. The emitter layer 150 is a gallium nitride based semiconductor layer including an n-type dopant such as Si, and is, for example, an n⁺-type GaN layer.

The collector electrode 160 is disposed on a rear surface 110b of the support substrate 110. The base electrode 170 is disposed on the principal surface of the base layer 140 at a distance from the emitter layer 150. The emitter electrode 180 is disposed on the principal surface of the emitter layer 150.

The method for manufacturing the bipolar transistor 100 comprises the steps of: epitaxially growing the collector layer 130 on the support substrate 110 with the buffer layer 120 being interposed therebetween; epitaxially growing the base layer 140 on the collector layer 130 at a temperature equal to or higher than 1000° C. by using hydrogen gas as a carrier gas; and epitaxially growing the emitter layer 150 on the base layer 140 by using at least one inactive gas selected from the group consisting of nitrogen gas, argon gas, helium gas and neon gas as a carrier gas. In the bipolar transistor 100 manufactured by such manufacturing method, the drain leakage current can be reduced in the same manner as in the heterojunction field effect transistor 1.

A bipolar transistor 200 shown in FIG. 6 is formed by laminating a buffer layer 220, a collector layer (first gallium nitride based semiconductor layer) 230, a base layer (second gallium nitride based semiconductor layer) 240, an emitter layer (third gallium nitride based semiconductor layer) 250, and an emitter cap layer 260 in the order of description on the principal surface of a support substrate 210.

The support substrate 210 is a free-standing Group III nitride substrate, such as a GaN substrate. The buffer layer 220 is a gallium nitride based semiconductor layer constituted by GaN or the like. The thickness of the buffer layer 220 is, for example, 2.0 μm.

The collector layer 230 is formed by laminating a sub-collector layer 230a, a collector layer 230b, and a collector layer 230c in the order of description on the principal surface of the support substrate 210. The sub-collector layer 230a is a gallium nitride based semiconductor layer constituted by GaN or the like, and includes, for example, an n-type dopant (Si or the like). The donor concentration of the sub-collector layer 230a is, for example, 2.0×10¹⁸ cm⁻³. The thickness of the sub-collector layer 230a is, for example, 500 nm.

The collector layer 230b is a gallium nitride based semiconductor layer constituted by GaN or the like, and includes, for example, an n-type dopant (Si or the like). The donor concentration of the collector layer 230b is, for example, 2.0×10¹⁷ cm⁻³. The thickness of the collector layer 230b is, for example, 200 nm.

The collector layer 230c is a gradient composition layer in which the indium composition is graded, for example, and is a gallium nitride based semiconductor layer in which the indium composition is graded from GaN at the collector layer 230b side to In_{0.03}Ga_{0.97}N at the base layer 240 side. For example, the collector layer 230c includes an n-type dopant (Si or the like), the donor concentration of the collector layer 230c is, for example, 2.0×10¹⁸ cm⁻³. The thickness of the collector layer 230c is, for example, 30 nm.

The base layer 240 is a gradient composition layer in which the indium composition is graded, for example, and is a gallium nitride based semiconductor layer in which the indium composition is graded from In_{0.03}Ga_{0.97}N at the collector layer 230 side to In_{0.06}Ga_{0.94}N at the emitter layer 250 side. The base layer 240 is a p-type semiconductor layer including a p-type dopant (Mg, Zn, or the like), the acceptor concentration of the base layer 240 is, for example, 2.5×10¹⁸ cm⁻³. The thickness of the base layer 240 is, for example, 100 nm.

The emitter layer 250 is a gradient composition layer in which the indium composition is graded, for example, and is a gallium nitride based semiconductor layer in which the indium composition is graded from In_{0.06}Ga_{0.94}N at the base layer 240 side to GaN at the emitter cap layer 260 side. For example, the emitter layer 250 includes an n-type dopant (Si or the like), the donor concentration of the emitter layer 250 is, for example, 1.0×10¹⁹ cm⁻³. The thickness of the emitter layer 250 is, for example, 30 nm.

The emitter cap layer 260 is a gallium nitride based semiconductor layer constituted by GaN or the like, and includes, for example, an n-type dopant (Si or the like). The donor concentration of the emitter cap layer 260 is, for example, 1.0×10¹⁹ cm⁻³. The thickness of the emitter cap layer 260 is, for example, 70 nm.

The method for manufacturing the bipolar transistor 200 comprises the steps of: epitaxially growing the collector layer 230 on the support substrate 210 with the buffer layer 220 being interposed therebetween; epitaxially growing the base layer 240 on the collector layer 230 at a temperature equal to or higher than 1000° C. by using hydrogen gas as a carrier gas; and epitaxially growing the emitter layer 250 on the base layer 240 by using at least one inactive gas selected from the group consisting of nitrogen gas, argon gas, helium gas and neon gas as a carrier gas. In the bipolar transistor 200 manufactured by such manufacturing method, the drain leakage current can be reduced in the same manner as in the heterojunction field effect transistor 1.

### EXAMPLES

The present invention will be described below in greater detail on the basis of examples, but the present invention is not limited to the examples.

### Comparative Example 1

First, 2 inch square of conductive gallium nitride substrate (GaN substrate) was disposed inside a growth furnace, and substrate cleaning was performed in ammonia and hydrogen atmosphere at 1030° C. and 100 Torr.

Then, a laminate constituted by an n-type GaN layer (drift layer, thickness: 5 μm, Si doping amount: 1×10¹⁶ cm⁻³), a p-type GaN layer (current blocking layer, thickness: 0.5 μm, Mg doping amount: 5×10¹⁸ cm⁻³), and an n⁺-type GaN layer (contact layer, thickness: 0.2 μm, Si doping amount: 1×10¹⁸ cm⁻³), was formed on the gallium nitride substrate in the following manner. The growth conditions of the respective semiconductor layers were the same with the exception of the dopant type, doping amount of the dopants, growth time and the like, the semiconductor layers were grown continuously to form the laminate, then the laminate temperature was lowered to room temperature. No heat treatment (activation annealing) was performed after the laminate was formed.

First, a laminate was obtained by forming an n-type GaN layer, a p-type GaN layer, and a n⁺-type GaN layer in the order of description under the conditions of a growth temperature of 1050° C., a growths pressure of 200 Torr, and a supply molar ratio (V/III)=1500 on a gallium nitride substrate by a MOCVD method. Trimethylgallium was used as a gallium starting material, high-purity ammonia was used as a nitrogen starting material, and purified hydrogen was used as a carrier gas. The purity of the high-purity ammonia was equal to or higher than 99.999%, and the purity of the purified hydrogen was equal to or higher than 99.999995%. Hydrogen-based silane was used as an n-type dopant gas, and biscyclopentadiethyl magnesium was used as a p-type dopant gas.

### Example 1

A laminate was obtained in the same manner as in Comparative Example 1, except that an n-type GaN layer and a p-type GaN layer were formed in the order of description on a gallium nitride substrate by using purified hydrogen as a carrier gas and an n⁺-type GaN layer was then formed on the p-type GaN layer by using nitrogen gas as a carrier gas. The ratio of the hydrogen concentration of the acceptor concentration in the laminate was 0.7.

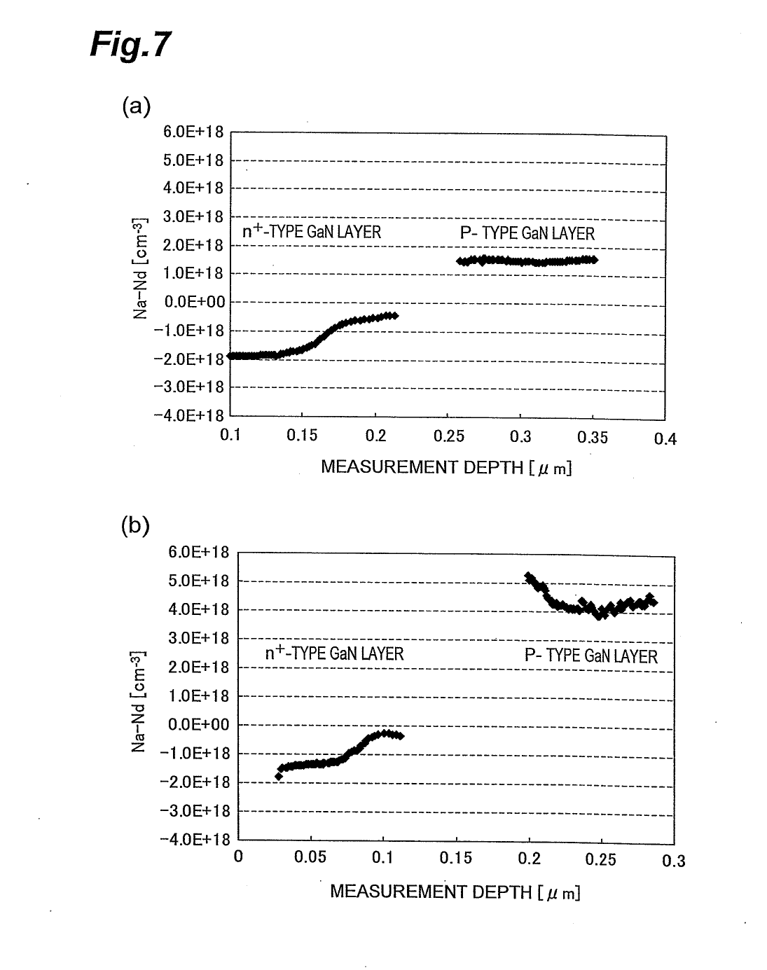

The electric capacitance measurements were performed with respect to the laminates obtained in Comparative Example 1 and Example 1 by electrochemical CV (ECV) measurements while conducting etching with a KOH solution from the n⁺-type GaN layer at the surface to the p-type GaN layer, to measure donor concentration and acceptor concentration in the depth direction. FIG. 7 shows the measurement results obtained in the ECV measurements. FIG. 7(a) shows the measurement result obtained in Comparative Example 1 and FIG. 7(b) shows the measurement result obtained in Example 1. The ordinate shows “acceptor concentration (Na)−donor concentration (Nd)” (cm⁻³), and the abscissa shows the measurement depth (μm) from the laminate surface. For example, “2.0E+18” at the ordinate represents 2.0×10¹⁸.

In the measurement results obtained in Comparative Example 1 (FIG. 7(a)), the donor of about 2.0×10¹⁸ cm⁻³ was found near the surface of the n⁺-type GaN layer (left side in the figure), and the donor concentration tends to decrease as the interface with the p-type GaN layer is approached. This supposedly indicates that when the epitaxial growth advanced from the p-type GaN layer to the n⁺-type GaN layer, Mg diffused from the p-type GaN layer into the n⁺-type GaN layer, and Si in the vicinity of the pn interface was compensated.

Further, in the p-type GaN layer, acceptors in a constant amount (about 1.5×10¹⁸ cm⁻³) can be found in a state in which no heat treatment is performed. On the other hand, separately from the above-described ECV measurements, after the laminates fabricated in the same manner as in Comparative Example 1 were respectively heat treated at 700° C. in a nitrogen atmosphere and in an atmosphere obtained by adding a constant amount (flow rate ratio 1 to 20%) of oxygen to nitrogen, the ECV measurements were conducted in the same manner as described hereinabove. As a result, it was confirmed that the acceptor concentration of the p-type GaN layer was mostly unchanged by comparison with before the heat treatment. This phenomenon is supposedly derived from the fact that, although the heat treatment was performed, the hydrogen atoms contained in the p-type GaN layer were blocked by the n⁺-type GaN layer and were not released to the outside of the laminate since the p-type GaN layer was capped by the n⁺-type GaN layer.

Further, separately from the above-described ECV measurements, the ECV measurements were conducted in the same manner as described hereinabove with respect to a laminate obtained in the same manner as in Comparative Example 1 except that no n⁺-type GaN layer was formed after forming the n-type GaN layer and the p-type GaN layer on a gallium nitride substrate in the order of description. As a result, in the p-type GaN layer exposed on the front surface of the laminate, the acceptor concentration was about 2.0×10¹⁷ cm⁻³ and was 1/10 or less of the Mg doping amount in a state in which no heat treatment was performed. This phenomenon is supposedly derived from the fact that most Mg contained in the p-type GaN layer was passivated by hydrogen atoms.

With respect to the abovementioned laminate in which the p-type GaN layer was exposed on the surface, the ECV measurements were conducted in the same manner as described hereinabove after the heat treatments were respectively conducted at 700° C. in a nitrogen atmosphere and in an atmosphere obtained by adding a constant amount (flow rate ratio 1 to 20%) of oxygen to nitrogen. As a result, the acceptor concentration was about 4.5×10¹⁸ cm⁻³ and was the same as the Mg doping amount. This phenomenon is supposedly derived from the fact that Mg contained in the p-type GaN layer was dissociated from hydrogen atoms by the heat treatment and released to the outside of the laminate.

In the measurement results obtained in Example 1 (FIG. 7(b)), it was confirmed that the profile of the donor in the n⁺-type GaN layer behaved in the same manner as in Comparative Example 1, but the acceptor concentration of the p-type GaN layer was about 4.0×10¹⁸ cm⁻³ and was higher than the acceptor concentration of 1.5×10¹⁸ cm⁻³ of Comparative Example 1. This phenomenon is supposedly derived from the fact that, in the laminate of Example 1, the p-type GaN layer was capped by the n⁺-type GaN layer in a state in which Mg had been dissociated from hydrogen atoms while the hydrogen concentration was being reduced, and the hydrogen atoms were prevented from being taken in the p-type GaN layer when the temperature was lowered in the subsequent step, whereby a high activity of Mg in the p-type GaN layer was maintained.

### REFERENCE SIGNS LIST

1: heterojunction field effect transistor (nitride semiconductor device), 10, 110, 210: support substrates (Group III nitride substrates), 20a: drift layer, 20b: current blocking layer, 20c: contact layer, 20d: channel layer, 20e: carrier supply layer, 25: laminate, 27: opening, 27a: side surface, 30: source electrode, 40: drain electrode, 50: insulating film, 60: gate electrode, 70a: semiconductor layer (first gallium nitride based semiconductor layer), 70b: semiconductor layer (second gallium nitride based semiconductor layer), 70c: semiconductor layer (third gallium nitride based semiconductor layer), 100, 200: bipolar transistors (nitride semiconductor devices), 130, 230: collector layers (first gallium nitride based semiconductor layers), 140, 240: base layers (second gallium nitride based semiconductor layers), 150, 250: emitter layers (third gallium nitride based semiconductor layers).

1. A method for manufacturing a nitride semiconductor device, comprising the steps of:
epitaxially growing a first gallium nitride based semiconductor layer on a free-standing Group III nitride substrate;
epitaxially growing a second gallium nitride based semiconductor layer which is a p-type semiconductor layer on the first gallium nitride based semiconductor layer at a temperature equal to or higher than 1000° C. by using hydrogen gas as a carrier gas; and
epitaxially growing a third gallium nitride based semiconductor layer on the second gallium nitride based semiconductor layer by using at least one gas selected from the group consisting of nitrogen gas, argon gas, helium gas, and neon gas as a carrier gas.

2. The method for manufacturing a nitride semiconductor device according to claim 1, wherein the third gallium nitride based semiconductor layer is an n-type semiconductor layer.

3. The method for manufacturing a nitride semiconductor device according to claim 1, wherein the first gallium nitride based semiconductor layer is an n-type semiconductor layer.

4. The method for manufacturing a nitride semiconductor device according to claim 1, wherein the second gallium nitride based semiconductor layer includes at least one element selected from the group consisting of magnesium and zinc as a dopant.

5. The method for manufacturing a nitride semiconductor device according to claim 1, wherein a ratio of a hydrogen concentration to an acceptor concentration in the second gallium nitride based semiconductor layer is less than 0.8.

6. The method for manufacturing a nitride semiconductor device according to claim 1, wherein a thickness of the third gallium nitride based semiconductor layer is 50 to 500 nm.

7. The method for manufacturing a nitride semiconductor device according to claim 1, wherein a combination of materials of the first to third gallium nitride based semiconductor layers is n⁺-type GaN/p-type GaN/n-type GaN, n⁺-type GaN/p-type AlGaN/n-type GaN, n⁺-type InGaN/p-type GaN/n-type GaN, or n⁺-type InGaN/p-type AlGaN/n-type GaN when represented as the third gallium nitride based semiconductor layer/the second gallium nitride based semiconductor layer/the first gallium nitride based semiconductor layer.

8. The method for manufacturing a nitride semiconductor device according to claim 1, further comprising the steps of:
forming an opening in the first gallium nitride based semiconductor layer for a drift layer, the second gallium nitride based semiconductor layer for a current blocking layer, and the third gallium nitride based semiconductor layer for a contact layer, the opening passing from the third gallium nitride based semiconductor layer to the first gallium nitride based semiconductor layer through the second gallium nitride based semiconductor layer, to obtain a laminate having the drift layer, the current blocking layer, the contact layer, and the opening;
epitaxially growing a channel layer constituted by a gallium nitride based semiconductor on a side surface of the opening;
epitaxially growing a carrier supply layer constituted by a Group III nitride semiconductor on the channel layer;
forming an insulating film on the carrier supply layer; and
forming a gate electrode on the insulating film, forming a source electrode on the laminate, and forming a drain electrode on the free-standing Group III nitride substrate or on the laminate, wherein
a bandgap of the carrier supply layer is greater than a bandgap of the channel layer.

9. The method for manufacturing a nitride semiconductor device according to claim 1, wherein
the nitride semiconductor device is a bipolar transistor comprising a collector layer, a base layer, and an emitter layer,
the collector layer is the first gallium nitride based semiconductor layer,
the base layer is the second gallium nitride based semiconductor layer containing indium, and
the emitter layer is the third gallium nitride based semiconductor layer.
